(19) United States
(12) Patent Application Publication
(10) Pub. No.: US 2025/0087504 A1
(43) Pub. Date: Mar. 13, 2025

(54) SEMICONDUCTOR PACKAGE CUTTING SYSTEM AND METHOD

(71) Applicant: SEMES CO., LTD., Cheonan-si (KR)

(72) Inventors: Changhoon OK, Cheonan-si (KR); Jae Gyeong LEE, Cheonan-si (KR); Jinsoo KIM, Cheonan-si (KR)

(73) Assignee: SEMES CO., LTD., Cheonan-si (KR)

(21) Appl. No.: 18/824,861

(22) Filed: Sep. 4, 2024

(30) Foreign Application Priority Data
Sep. 7, 2023 (KR) 10-2023-0118944

(51) Int. Cl. H01L 21/67; H01L 21/48; H01L 21/66

(52) U.S. Cl. CPC H01L 21/67092; H01L 21/4842; H01L 21/67288; H01L 22/12

(57) ABSTRACT

Provided is a semiconductor package cutting system including a loading device storing at least one strip or at least one magazine containing the strip, a cutting device mounted behind the loading device to partial-cut at least a portion of the strip supplied from the loading device, an inspection device mounted behind the cutting device to inspect the strip cut by the cutting device, and an unloading device mounted behind the inspection device to unload the inspected strip.

### CROSS-REFERENCE TO RELATED PATENT APPLICATION

This application claims the benefit of Korean Patent Application No. 10-2023-0118944, filed on Sep. 7, 2023, in the Korean Intellectual Property Office, the disclosure of which is incorporated herein in its entirety by reference.

### BACKGROUND OF THE INVENTION

### 1. Field of the Invention

The present invention relates to a semiconductor package cutting system and method and, more particularly, to a semiconductor package cutting system and method capable of partial-cutting portions of semiconductor packages disposed on a strip, in a semiconductor device manufacturing process.

### 2. Description of the Related Art

In general, semiconductor devices may be formed on a silicon wafer used as a semiconductor substrate by repeatedly performing a series of manufacturing processes, and the semiconductor devices formed as described above may be produced as a semiconductor strip including a plurality of semiconductor packages through dicing, die bonding, and molding processes.

The semiconductor strip may be individualized into a plurality of semiconductor packages and then the semiconductor packages may be sorted into defective or non-defective products through a sawing and sorting process. For example, a sawing and sorting apparatus may include a cutting device for loading a semiconductor strip on a chuck table and then individualizing the semiconductor strip into a plurality of semiconductor packages by using a cutting blade, and an inspection device for cleaning and drying the individualized semiconductor packages, inspecting the semiconductor packages by using an inspection camera, and then sorting and unloading the semiconductor packages based on the inspection results.

Currently, as demands for small semiconductors are increased due to the rapid growth of the mobility industry, demands for a partial-cutting process capable of increasing wettability by cutting portions of the semiconductor packages before the sawing and sorting process are also increasing.

Although the above-described partial-cutting process has been performed by modifying an existing sawing and sorting apparatus, because an inspection device of the existing sawing and sorting apparatus is used, an additional storage unit is required to store partial-cut semiconductor strips, and thus the cost for the partial-cutting process and the footprint of the entire equipment are increased.

### SUMMARY OF THE INVENTION

The present invention provides a semiconductor package cutting system and method capable of performing a partial-cutting process by self-loading and unloading materials without an additional storage unit. However, the above description is an example, and the scope of the present invention is not limited thereto.

According to an aspect of the present invention, there is provided a semiconductor package cutting system including a loading device storing at least one strip or at least one magazine containing the strip, a cutting device mounted behind the loading device to partial-cut at least a portion of the strip supplied from the loading device, an inspection device mounted behind the cutting device to inspect the strip cut by the cutting device, and an unloading device mounted behind the inspection device to unload the inspected strip.

The inspection device may include an inspection table for placing thereon the strip cut by the cutting device, and being movable back and forth in a first direction, a vision unit mounted on a path of the inspection table to inspect a cut depth of the strip, and outlet rails for placing thereon the strip transferred from the inspection table.

The unloading device may be mounted on a rear portion of the inspection device, and the outlet rails may include first outlet rails extending in the first direction toward the unloading device to place thereon the strip supplied from the inspection table.

The unloading device may be mounted on a side portion of the inspection device, and the outlet rails may include second outlet rails extending in a second direction toward the unloading device to place thereon the strip transferred from the inspection table.

The inspection table may be rotatable about a third direction to rotate the strip placed thereon.

The loading device may include a loading pusher for moving the strip in a second direction to supply the strip to the cutting device.

The cutting device may include inlet rails extending in a second direction to place thereon the strip supplied from the loading device, a chuck table for receiving and fixing the strip aligned on the inlet rails, and being rotatable to rotate the strip, a cutting unit including a replaceable blade to partial-cut at least a portion of the strip fixed to the chuck table, and a cleaning unit for cleaning a surface or another surface of the cut strip.

The cutting device may further include a strip picker for moving the strip positioned on one of the inlet rails, the chuck table, the cutting unit, and the cleaning unit to another or to an inspection table of the inspection device so as to perform a plurality of processes on the strip.

The strip picker may include a first strip picker for moving the strip placed on the inlet rails to the chuck table, and a second strip picker for moving the strip cut on the chuck table to the cleaning unit and moving the strip cleaned by the cleaning unit to the inspection table.

According to another aspect of the present invention, there is provided a semiconductor package cutting method including (a) moving a strip from a loading device storing the strip or a magazine containing the strip, to a cutting device, (b) partial-cutting at least a portion of the strip by using the cutting device, (c) moving the cut strip to an inspection device and inspecting a cut depth, and (d) storing the inspected strip in an unloading device.

### BRIEF DESCRIPTION OF THE DRAWINGS

The above and other features and advantages of the present invention will become more apparent by describing in detail embodiments thereof with reference to the attached drawings in which:

FIG. 1 is a top view of a semiconductor package cutting system according to an embodiment of the present invention;

FIGS. 2 and 3 are top views of a semiconductor package cutting system according to another embodiment of the present invention;

FIG. 4 is a flowchart of a semiconductor package cutting method according to an embodiment of the present invention;

FIG. 5 is a cross-sectional view of a semiconductor package which is not partial-cut; and

FIG. 6 is a cross-sectional view of a semiconductor package which is partial-cut based on a semiconductor package cutting system and method according to embodiments of the present invention.

### DETAILED DESCRIPTION OF THE INVENTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the thicknesses or sizes of layers are exaggerated for clarity and convenience of explanation.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing.

In the following description, a first direction refers to the y-axis direction in the drawings, a second direction refers to the x-axis direction, and a third direction refers to a direction perpendicular to the x-axis and y-axis directions. Further, in relation to strips described herein, for convenience and clarity of explanation, a strip before being cut is referred to as a first strip and a strip after being cut is referred to as a second strip, and the first and second strips are not different strips.

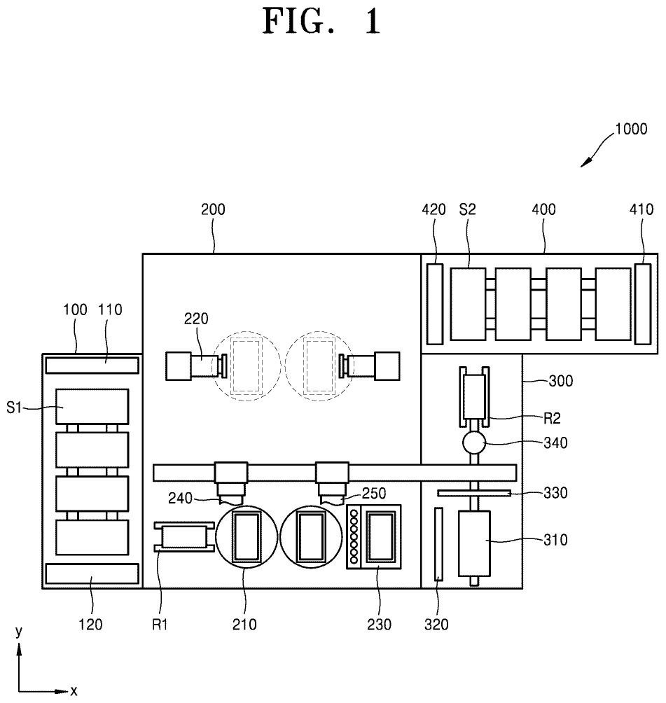

FIG. 1 is a top view of a semiconductor package cutting system 1000 according to an embodiment of the present invention. As shown in FIG. 1, the semiconductor package cutting system 1000 may include a loading device 100 for supplying a strip S, a cutting device 200 for partial-cutting portions of semiconductor packages mounted on the strip S, an inspection device 300 for inspecting the cut strip S, and an unloading device 400 for unloading the inspected strip S.

Specifically, a plurality of first strips S1 which are not cut may be stored in the loading device 100. The first strip S1 may be transferred by a loading elevator 110 to a position accessible to the cutting device 200, and then transferred by a pusher 120 onto inlet rails R1 mounted on the cutting device 200.

The cutting device 200 may include a chuck table 210 for supporting and fixing the first strip S1, a cutting unit 220 for partial-cutting portions of semiconductor packages on the first strip S1 fixed to the chuck table 210, and a cleaning unit 230 for cleaning and drying a second strip S2 which is cut.

Specifically, the cutting unit 220 may include a circular blade for partial-cutting at least portions of a plurality of semiconductor packages disposed on the strip. For example, the circular blade may be moved in a first direction, and the first strip S1 fixed onto the chuck table 210 may be partial-cut (or half-cut) while the chuck table 210 is being moved in a second direction. The cleaning unit 230 may clean the second strip S2 by using a brush or a cleaning solution to remove particles or foreign substances produced during the cutting process.

The cutting device 200 may further include a strip picker for moving the strip positioned on one of the inlet rails R1, the cutting unit 220, and the cleaning unit 230 to another so as to perform a plurality of processes on the first strip S1.

Specifically, the strip picker may include a first strip picker 240 for moving the first strip S1 placed on the inlet rails R1 to the chuck table 210, and a second strip picker 250 for moving the second strip S2 cut on the chuck table 210 to the cleaning unit 230 and moving the second strip S2 cleaned by the cleaning unit 230 to the inspection device 300.

The first and second strip pickers 240 and 250 may move back and forth along the second direction, and the inlet rails R1, the chuck table 210, and the cleaning unit 230 may be disposed along the second direction.

Therefore, the first strip S1 brought onto the inlet rails R1 by the pusher 120 of the loading device 100 may be transferred to the chuck table 210 by the first strip picker 240, and the second strip S2 partial-cut on the chuck table 210 by the cutting unit 220 may be transferred to the cleaning unit 230 and then transferred to the inspection device 300 after being cleaned, by the second strip picker 250.

The inspection device 300 may include an inspection table 310 for placing thereon the partial-cut and cleaned second strip S2 transferred by the second strip picker 250 of the cutting device 200, and being movable back and forth in the first direction, first and second drying units 320 and 330 for drying a surface and another surface of the second strip S2, a vision unit 340 for inspecting a cut depth of the second strip S2, and outlet rails R2 for placing thereon the second strip S2 transferred by the inspection table 310.

In this case, the first drying unit 320 may be mounted on a path along which the second strip S2 is transferred by the second strip picker 250, to dry the surface of the second strip S2, and the second drying unit 330 may be mounted on a path along which the second strip S2 is transferred to the vision unit 340 by the inspection table 310, to dry the other surface of the second strip S2. Alternatively, the first drying unit 320 may dry the other surface of the second strip S2 and the second drying unit 330 may dry the surface of the second strip S2.

Specifically, a plurality of second strips S2 which are cut and inspected may be stored in the unloading device 400. The second strip S2 may be transferred from the outlet rails R2 mounted on the inspection device 300 into the unloading device 400 by an unloading pusher 420, and then transferred to a storage position by an unloading elevator 410. The unloading pusher 420 may be a type of pusher block capable of pushing the second strip S2 from the outlet rails R2 into the unloading device 400, or be a type of gripper or strip picker capable of bringing the second strip S2 placed on the outlet rails R2, into the unloading device 400 by gripping the second strip S2.

In this case, the unloading device 400 of the semiconductor package cutting system 1000 according to an embodiment of the present invention may be mounted behind the inspection device 300 on a rear portion of the inspection device 300 with respect to the first direction. Therefore, the outlet rails R2 of the inspection device 300 may extend in the first direction toward the unloading device 400 to place thereon the second strip S2 transferred by the inspection table 310 and to transfer the second strip S2 to the unloading device 400.

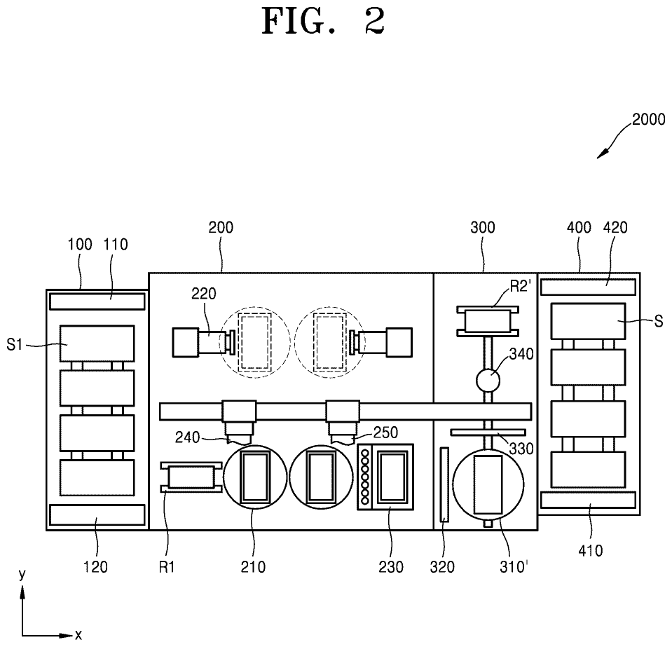

As shown in FIG. 2, the unloading device 400 of a semiconductor package cutting system 2000 according to another embodiment of the present invention may be mounted behind the inspection device 300 on a side portion of the inspection device 300 with respect to the second direction. Therefore, outlet rails R2′ of the inspection device 300 may extend in the second direction toward the unloading device 400 to place thereon the second strip S2 transferred by the inspection table 310 and to transfer the second strip S2 to the unloading device 400.

In this case, an inspection table 310′ may receive the second strip S2 aligned in the first direction and transferred by the second strip picker 250, and then rotate about a third direction to place the second strip S2 on the outlet rails R2′.

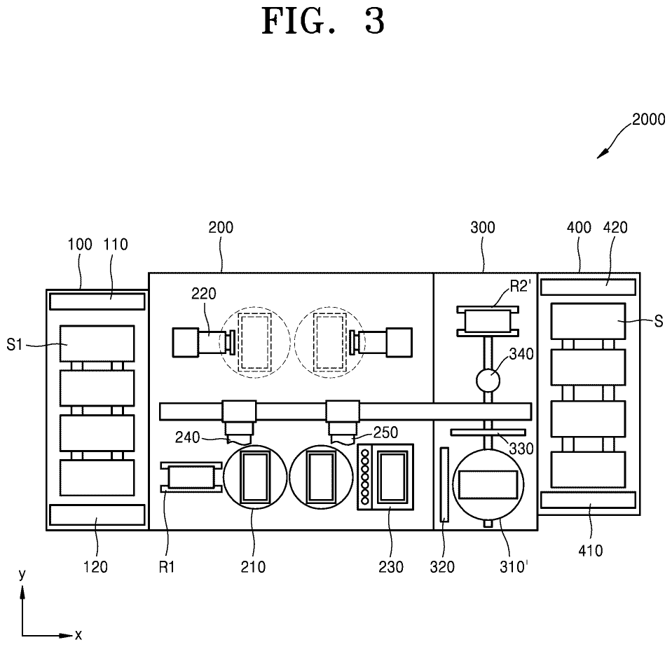

Therefore, the inspection table 310′ may receive the second strip S2 from the second strip picker 250 as shown in FIG. 2, and then rotate as shown in FIG. 3 to place the second strip S2 on the outlet rails R2′ through the second drying unit 330 and the vision unit 340.

The disposition of the unloading device 400 of the semiconductor package cutting systems 1000 and 2000 according to embodiments of the present invention may be changed depending on an installation space of the entire system. For example, depending on the equipment, when there is a free space near the rear portion of the inspection device 300, the unloading device 400 may be mounted on the rear portion of the inspection device 300 as described above in relation to the first embodiment and, when there is no free space near the rear portion of the inspection device 300, the unloading device 400 may be mounted on the side portion of the inspection device 300 as described above in relation to the second embodiment.

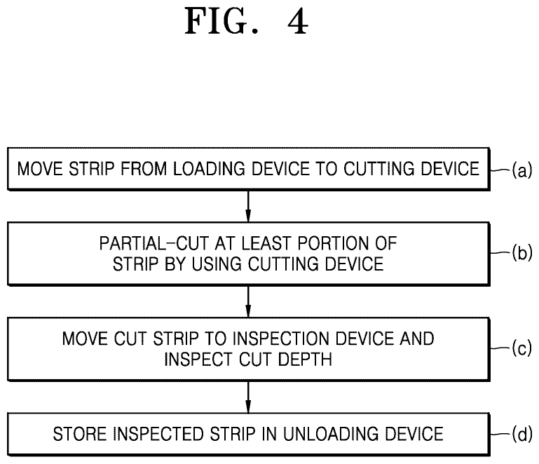

FIG. 4 is a flowchart of a semiconductor package cutting method according to an embodiment of the present invention. As shown in FIG. 4, the semiconductor package cutting method according to an embodiment of the present invention may include (a) moving a strip from a loading device storing the strip or a magazine containing the strip, to a cutting device, (b) partial-cutting at least a portion of the strip by using the cutting device, (c) moving the cut strip to an inspection device and inspecting a cut depth, and (d) storing the inspected strip in an unloading device.

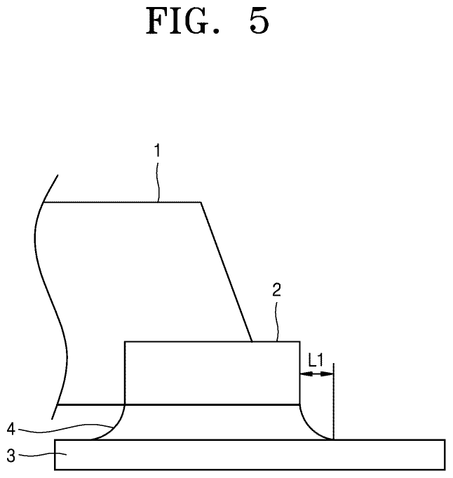

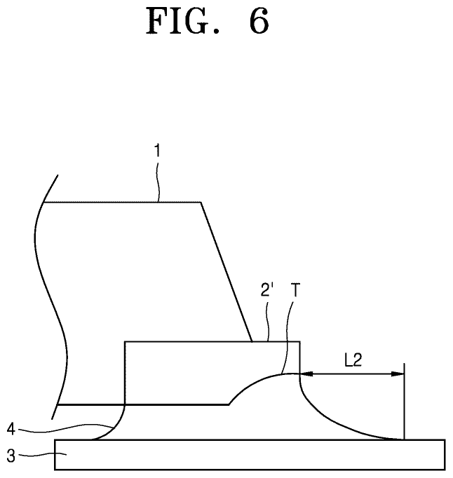

In this case, step (b) for partial-cutting at least a portion of the strip may include partial-cutting a portion of a terminal 2 of a semiconductor package 1 disposed on the strip, as shown in FIGS. 5 and 6.

FIG. 5 shows a general semiconductor package which is not partial-cut. Initially, as shown in FIG. 5, when the semiconductor package 1 is mounted on a substrate 3 through a reflow process of solder 4, the solder 4 exhibits a wetting shape having a first length L1.

Comparatively, as shown in FIG. 6, when a cutout T is formed by partial-cutting a portion of the terminal 2′ of the semiconductor package 1 based on the semiconductor package cutting system and method according to embodiments of the present invention, the solder 4 exhibits a wetting shape having a second length L2 greater than the first length L1, which means that wettability is improved.

Consequently, based on the semiconductor package cutting system and method according to embodiments of the present invention, footprint may be reduced because strips are self-loadable and unloadable without an additional storage unit, space may be efficiently used because the disposition of an unloading device is changeable depending on an installation space of the entire system, an existing sawing and sorting apparatus may be used as a cutting device of the present invention by merely replacing a blade thereof, transition to a subsequent process may be easily enabled by docking additional equipment at the rear of the unloading device, and wettability may be improved by partial-cutting semiconductor packages with the cutting device.

According to the afore-described embodiments of the present invention, footprint may be reduced because strips are self-loadable and unloadable without an additional storage unit, space may be efficiently used because the disposition of an unloading device is changeable depending on an installation space of the entire system, and versatility may be achieved because a cutting device is usable as an existing sawing and sorting apparatus by merely replacing a blade thereof. However, the scope of the present invention is not limited to the above effects.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. A semiconductor package cutting system comprising:
a loading device storing at least one strip or at least one magazine containing the strip;
a cutting device mounted behind the loading device to partial-cut at least a portion of the strip supplied from the loading device;
an inspection device mounted behind the cutting device to inspect the strip cut by the cutting device; and
an unloading device mounted behind the inspection device to unload the inspected strip.

2. The semiconductor package cutting system of claim 1, wherein the inspection device comprises:
an inspection table for placing thereon the strip cut by the cutting device, and being movable back and forth in a first direction;
a vision unit mounted on a path of the inspection table to inspect a cut depth of the strip; and
outlet rails for placing thereon the strip transferred from the inspection table.

3. The semiconductor package cutting system of claim 2, wherein the unloading device is mounted on a rear portion of the inspection device, and
wherein the outlet rails comprise first outlet rails extending in the first direction toward the unloading device to place thereon the strip supplied from the inspection table.

4. The semiconductor package cutting system of claim 2, wherein the unloading device is mounted on a side portion of the inspection device, and
wherein the outlet rails comprise second outlet rails extending in a second direction toward the unloading device to place thereon the strip transferred from the inspection table.

5. The semiconductor package cutting system of claim 4, wherein the inspection table is rotatable about a third direction to rotate the strip placed thereon.

6. The semiconductor package cutting system of claim 2, wherein the loading device comprises a loading pusher for moving the strip in a second direction to supply the strip to the cutting device.

7. The semiconductor package cutting system of claim 1, wherein the cutting device comprises:
inlet rails extending in a second direction to place thereon the strip supplied from the loading device;
a chuck table for receiving and fixing the strip aligned on the inlet rails, and being rotatable to rotate the strip;
a cutting unit comprising a replaceable blade to partial-cut at least a portion of the strip fixed to the chuck table; and
a cleaning unit for cleaning a surface or another surface of the cut strip.

8. The semiconductor package cutting system of claim 7, wherein the cutting device further comprises a strip picker for moving the strip positioned on one of the inlet rails, the chuck table, the cutting unit, and the cleaning unit to another or to an inspection table of the inspection device so as to perform a plurality of processes on the strip.

9. The semiconductor package cutting system of claim 8, wherein the strip picker comprises:
a first strip picker for moving the strip placed on the inlet rails to the chuck table; and
a second strip picker for moving the strip cut on the chuck table to the cleaning unit and moving the strip cleaned by the cleaning unit to the inspection table.

10. A semiconductor package cutting method comprising:
(a) moving a strip from a loading device storing the strip or a magazine containing the strip, to a cutting device;
(b) partial-cutting at least a portion of the strip by using the cutting device;
(c) moving the cut strip to an inspection device and inspecting a cut depth; and
(d) storing the inspected strip in an unloading device.
